(19) United States
(12) Patent Application Publication
(10) Pub. No.: US 2026/0117362 A1
(43) Pub. Date: Apr. 30, 2026

(54) SUBSTRATE PROCESSING METHOD, SUBSTRATE PROCESSING APPARATUS, AND HARD MASK

(71) Applicant: Tokyo Electron Limited, Tokyo (JP)

(72) Inventors: Takuya SEINO, Gyeonggi-do (KR); Toru KITADA, Yamanashi (JP); Shota ISHIBASHI, Yamanashi (JP); Sho KUMAKURA, Miyagi (JP)

(21) Appl. No.: 19/431,222

(22) Filed: Dec. 23, 2025

Related U.S. Application Data
(63) Continuation of application No. PCT/JP2024/023403, filed on Jun. 27, 2024.

(30) Foreign Application Priority Data
Jul. 5, 2023 (JP) 2023-110833

(51) Int. Cl. C23C 14/06; C23C 14/34; C23C 14/54

(52) U.S. Cl. CPC C23C 14/06; C23C 14/3464; C23C 14/548

(57) ABSTRACT

A substrate processing method includes preparing a substrate having a silicon-containing film, and forming a hard mask on the silicon-containing film by sputtering. The hard mask is an amorphous film containing tungsten, silicon, and nitrogen.

### CROSS-REFERENCE TO RELATED APPLICATIONS

This application is a continuation application of International Application No. PCT/JP2024/023403 filed on Jun. 27, 2024, and designated the U.S., which is based upon and claims priority to Japanese Patent Application No. 2023-110833 filed on Jul. 5, 2023, the entire contents of which are incorporated herein by reference.

### BACKGROUND

### 1. Technical Field

The present disclosure relates to a substrate processing method, a substrate processing apparatus, and a hard mask.

### 2. Description of Related Art

In the fabrication of electronic devices, such as semiconductor devices, plasma etching is often employed to form openings, such as holes or grooves, in a silicon-containing film. When plasma etching is performed to define these openings, a mask is formed over the surface of the silicon-containing film. Resist masks are known as masks used for this purpose.

In recent years, elements in electronic devices have three-dimensional structures. Accordingly, substantially deep openings are formed in silicon-containing films. Because resist masks tend to be rapidly consumed during plasma etching of silicon-containing films, hard masks are employed instead. As a hard mask, a hard mask formed of tungsten silicide (WSi) or titanium nitride (TiN) is used, as described in Patent Documents 1 to 4.

Patent Document 1: Japanese Unexamined Patent Application Publication No. 2007-294836

Patent Document 2: Japanese Unexamined Patent Application Publication No. 2003-243526

Patent Document 3: Japanese Unexamined Patent Application Publication No. 2005-150403

Patent Document 4: U.S. Patent Application Publication No. 2019/0019675

### SUMMARY

According to one aspect of the present disclosure, a substrate processing method including preparing a substrate having a silicon-containing film, and forming a hard mask on the silicon-containing film by sputtering, wherein the hard mask is an amorphous film containing tungsten, silicon, and nitrogen, is provided.

### BRIEF DESCRIPTION OF THE DRAWINGS

FIG. 1 is a flowchart illustrating a substrate processing method according to an embodiment;

FIG. 2A is an example of a schematic cross-sectional view of a wafer in a step of the substrate processing method;

FIG. 2B is an example of a schematic cross-sectional view of the wafer in a step of the substrate processing method;

FIG. 2C is an example of a schematic cross-sectional view of the wafer in a step of the substrate processing method;

FIG. 2D is an example of a schematic cross-sectional view of the wafer in a step of the substrate processing method;

FIG. 2E is an example of a schematic cross-sectional view of the wafer in a step of the substrate processing method;

FIG. 2F is an example of a schematic cross-sectional view of the wafer in a step of the substrate processing method;

FIG. 3 is an example of a schematic cross-sectional view of a substrate processing apparatus according to an embodiment;

FIG. 4A is an example of a schematic cross-sectional view illustrating an example of processing of a hard mask according to a comparative example;

FIG. 4B is an example of a schematic cross-sectional view illustrating an example of processing of the hard mask according to the comparative example;

FIG. 4C is an example of a schematic cross-sectional view illustrating an example of processing of the hard mask according to the comparative example;

FIG. 4D is an example of a schematic cross-sectional view illustrating an example of processing of the hard mask according to the comparative example;

FIG. 5 is an example of a cross-sectional view of the hard mask according to the comparative example taken along line A-A of FIG. 4C;

FIG. 6A is an example of a schematic cross-sectional view illustrating an example of processing of a hard mask according to a present embodiment;

FIG. 6B is an example of a schematic cross-sectional view illustrating an example of processing of the hard mask according to the present embodiment;

FIG. 6C is an example of a schematic cross-sectional view illustrating an example of processing of the hard mask according to the present embodiment;

FIG. 6D is an example of a schematic cross-sectional view illustrating an example of processing of the hard mask according to the present embodiment;

FIG. 7 is an example of a cross-sectional view of the hard mask according to the present embodiment taken along line B-B of FIG. 6C;

FIG. 8A is another example of the hard mask according to the present embodiment; and

FIG. 8B is the other example of the hard mask according to the present embodiment.

### DETAILED DESCRIPTION

According to one aspect, a substrate processing method, a substrate processing apparatus, and a hard mask, which are capable of obtaining a stable etched shape, are provided.

Hereinafter, embodiments of the present disclosure will be described with reference to the drawings. In each of the drawings, the same components are denoted by the same reference numerals, and redundant descriptions may be omitted.

### Substrate Processing Method

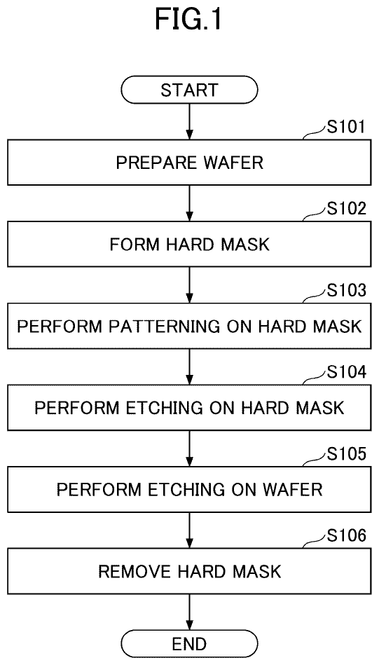

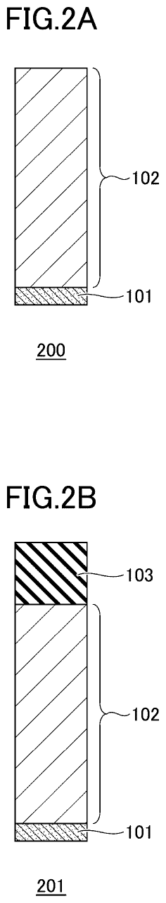

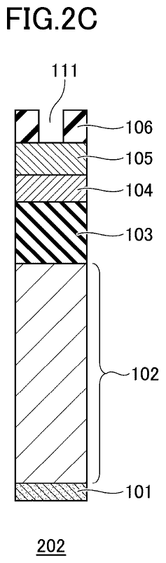

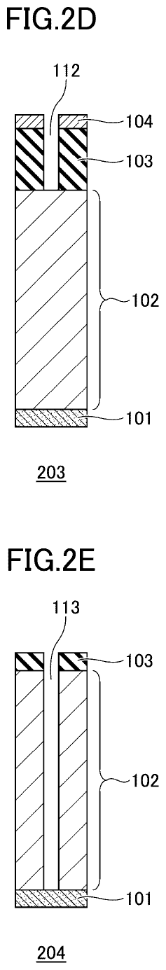

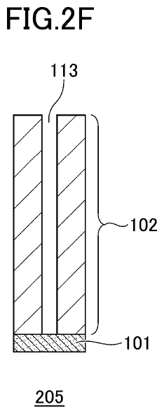

A substrate processing method according to an embodiment will be described with reference to FIGS. 1 and 2A through 2F. FIG. 1 is a flowchart for explaining a substrate processing method according to an embodiment. FIGS. 2A through 2F are schematic cross-sectional views of a wafer in each step of the method.

In step S101, a wafer 200 is prepared. FIG. 2A is a schematic cross-sectional view of the wafer 200 prepared in step S101.

The prepared wafer 200 has a base 101. The base 101 is, for example, a substrate made of silicon (Si). A base film 102 is formed on the base 101. The base film 102 is an etching-target film (a film to be etched) in which a pattern of openings is formed by plasma etching (refer to the description of step S105 below) using a hard mask 103, which is described later. The base film 102 is, for example, a silicon-containing film. The silicon-containing film of the base film 102 may be a single-layer film having any one of a monocrystalline silicon film, a polycrystalline silicon film, a silicon oxide film, and a silicon nitride film. The silicon-containing film of the base film 102 may be a multilayer film having two or more films selected from a monocrystalline silicon film, a polycrystalline silicon film, a silicon oxide film, and a silicon nitride film.

In step S102, formation of the hard mask 103 is performed on the wafer 200, FIG. 2B is a schematic cross-sectional view of a wafer 201 after the processing in step S102.

The hard mask 103 is an amorphous film (WSiN film) containing tungsten (W), silicon (Si), and nitrogen (N). The hard mask 103 may also contain boron (B).

In the hard mask 103, the composition may, for example, include 60 at.% tungsten, 25 at.% silicon, and 15 at.% nitrogen. Here, “at.%” represents atomic percent. It should be understood that the atomic composition ratio of the respective elements in the hard mask 103 is not limited to this example.

Preferably, the atomic concentration of tungsten (W) is 50 to 60 at %, that of silicon (Si) is 20 to 30 at.%, that of nitrogen (N) is 15 to 25 at.%, and that of boron (B) is 0 to 15 at.%. The total atomic concentration of these elements is 100 at.%.

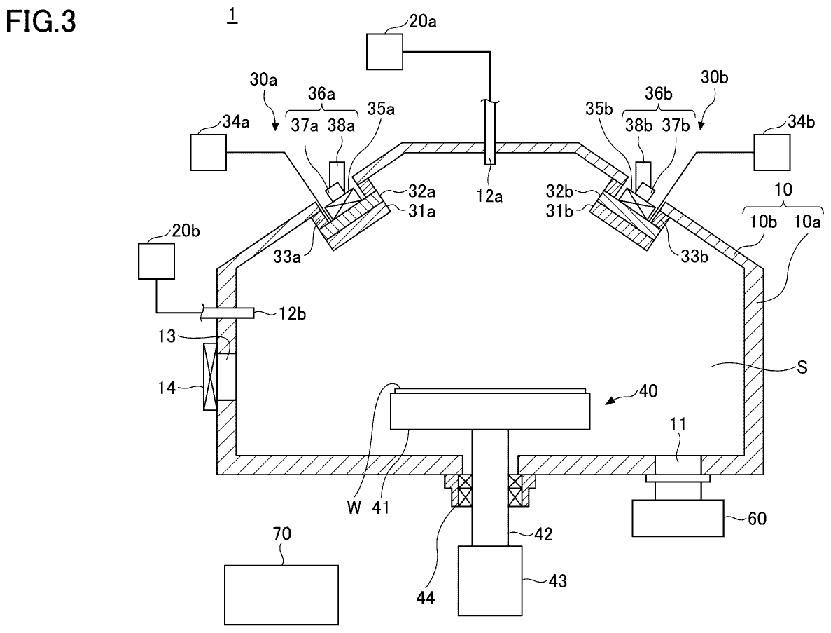

An example of the substrate processing apparatus 1 configured to form the hard mask 103 will be described later with reference to FIG. 3.

In step S103, patterning is performed on the hard mask 103. FIG. 2C is an example of a schematic cross-sectional view of a wafer 202 after the processing in step S103.

In step S103, a silicon oxide film 104 is formed over the hard mask 103. The silicon oxide film 104 may be formed by a chemical vapor deposition method or an atomic layer deposition method. An amorphous carbon film 105 is formed over the silicon oxide film 104. The amorphous carbon film 105 may be formed of spin-on carbon (SOC). The silicon oxide film 104 and the amorphous carbon film 105 are films used as masks when the hard mask 103 is etched (refer to the description of step S104).

A resist film 106 having a pattern of openings 111 is formed over the silicon oxide film 104. Specifically, the resist film 106 is formed over the silicon oxide film 104, and the resist film 106 having a pattern of openings 111 is formed by exposure and development.

The silicon oxide film 104, the amorphous carbon film 105, and the resist film 106 are used as masks when the hard mask 103 is etched; however, the present embodiment is not limited to this example.

In step S104, the hard mask 103 is etched. FIG. 2D is an example of a schematic cross-sectional view of a wafer 203 after the processing in step S104.

In step S104, the silicon oxide film 104 and the amorphous carbon film 105 are etched to form a pattern of openings in the silicon oxide film 104 and the amorphous carbon film 105, using the resist film 106 having a pattern of openings 111 as a mask. To etch the silicon oxide film 104 and the amorphous carbon film 105, anisotropic etching using plasma of a gas containing halogen atoms can be adopted.

Thereafter, the hard mask 103 is etched to form a pattern of openings 112 in the hard mask 103, using the silicon oxide film 104 and the amorphous carbon film 105 having a pattern of openings as a mask. When the hard mask 103 is etched, a step of etching the hard mask 103 and a step of oxidizing sidewalls of the recesses (openings 112) of the hard mask 103 are alternately repeated. For the step of etching the hard mask 103, anisotropic etching using plasma of a gas containing halogen atoms can be adopted.

For the step of oxidizing sidewalls of the recesses of the hard mask 103, an oxygen-containing plasma can be used.

In step S105, the wafer 203 is etched. FIG. 2E is an example of a schematic cross-sectional view of a wafer 204 after the processing in step S105.

In step S105, the base film 102 is etched using the hard mask 103 having a pattern of openings 112 as a mask, and a pattern of openings 113 is formed in the base film 102. For the etching of the base film 102 (silicon-containing film) performed in step S105, anisotropic etching using plasma of a fluorocarbon gas or plasma of a hydrofluorocarbon gas may be adopted, for example.

In step S106, the hard mask 103 is removed. FIG. 2F is an example of a schematic cross-sectional view of a wafer 205 after the processing in step S106.

As illustrated in FIG. 2F, the hard mask 103 is removed. According to the substrate processing method illustrated in FIG. 1, a pattern of openings 113 is thus formed in the base film 102 of the wafer 200.

### Substrate Processing Apparatus

Next, the substrate processing apparatus 1 for forming the hard mask 103 will be described with reference to FIG. 3. FIG. 3 is a schematic cross-sectional view of the substrate processing apparatus 1 according to an embodiment.

The substrate processing apparatus 1 includes a processing chamber 10, gas suppliers 20a and 20b, sputtered particle ejectors 30a and 30b, a substrate support 40, an exhaust device 60, and a controller 70. The substrate processing apparatus 1 is, for example, a PVD (physical vapor deposition) apparatus configured to form a film by depositing sputtered particles (film-forming atoms) ejected from the sputtered particle ejectors 30a and 30b and processing gas on the surface of a wafer W, such as a semiconductor wafer, mounted on the substrate support 40 in the processing chamber 10.

The processing chamber 10 has a chamber body 10a having an open upper portion, and a lid 10b provided to close the upper opening of the chamber body 10a. The side surface of the lid 10b is formed as an inclined surface. The inside of the processing chamber 10 is a processing space S within which film forming processing is performed.

An exhaust port 11 is formed at the bottom of the processing chamber 10. The exhaust device 60 is connected to the exhaust port 11. The exhaust device 60 includes a pressure control valve and a vacuum pump. The processing space S is evacuated to a predetermined degree of vacuum by the exhaust device 60.

Gas introduction ports 12a and 12b for introducing gas into the processing space S are inserted into the processing chamber 10. The gas supplier 20a is connected to the gas introduction port 12a. The gas supplier 20b is connected to the gas introduction port 12b. The gas supplier 20a supplies a sputtering gas into the processing space S through the gas introduction port 12a. In the present example, the sputtering gas is, for example, an inert gas. In the description hereinafter, a case where the sputtering gas is argon (Ar) gas will be described as an example. The gas supplier 20b supplies a processing gas containing a material including a constituent element of a film to be formed into the processing space S through the gas introduction port 12b. In the present example, the processing gas is a gas containing nitrogen (N). In the description hereinafter, a case where the processing gas is N₂ gas will be described as an example.

A loading and unloading port 13 through which the wafer W is loaded and unloaded is formed on a side wall of the processing chamber 10. The loading and unloading port 13 is opened and closed by a gate valve 14. The processing chamber 10 is provided adjacent to the transfer chamber (not illustrated), and the processing chamber 10 and the transfer chamber (not illustrated) communicate when the gate valve 14 is open. The inside of the transfer chamber (not illustrated) is maintained at a predetermined degree of vacuum, and provided with a transfer device (not illustrated) configured to load and unload the wafer W into and out of the processing chamber 10.

The sputtered particle ejector 30a has a target (first target) 31a, a target holder 32a, an insulating member 33a, a power supply 34a, a magnet 35a, and a magnet scanning mechanism 36a. The sputtered particle ejector 30b has a target (second target) 31b, a target holder 32b, an insulating member 33b, a power supply 34b, a magnet 35b, and a magnet scanning mechanism 36b.

The targets 31a and 31b are made of materials containing a constituent element of a film to be formed. The target 31a is formed of a first material. The target 31b is formed of a second material. In the present example, the target 31a is a target containing, for example, tungsten (W). The target 31b is a target containing tungsten (W) and silicon (Si), for example. When boron (B) is to be contained in a film to be formed, a target containing boron (B) is used as one of the target 31a or the target 31b or both of them.

The target holders 32a and 32b are made of a conductive material, and are attached via the insulating members 33a and 33b to the inclined surface of the lid 10b of the processing chamber 10 at positions different from each other. The target holders 32a and 32b hold the targets 31a and 31b in such a manner that the targets 31a and 31b are positioned obliquely above the wafer W supported by the substrate support 40.

The power supplies 34a and 34b are electrically connected to the target holders 32a and 32b, respectively. The power supplies 34a and 34b may be direct current power supplies in the case where the targets 31a and 31b are made of a conductive material; the power supplies 34a and 34b may be radio frequency power supplies in the case where the targets 31a and 31b are made of a dielectric material. In the latter case, the power supplies 34a and 34b are connected to the target holders 32a and 32b via matching devices. When a voltage is applied to the target holders 32a and 32b, sputtering gas is dissociated around the targets 31a and 31b. Then, the ions in the dissociated sputtering gas collide with the targets 31a and 31b, and sputtered particles, which are particles of the constituent material of the targets 31a and 31b, are ejected from the targets 31a and 31b.

The magnets 35a and 35b are arranged on the rear surface side of the target holders 32a and 32b, and are configured to reciprocate (swing) by the magnet scanning mechanisms 36a and 36b. The magnet scanning mechanisms 36a and 36b have, for example, guides 37a and 37b and drivers 38a and 38b. The magnets 35a and 35b are guided by the guides 37a and 37b so that the magnets 35a and 35b can reciprocate. The drivers 38a and 38b cause the magnets 35a and 35b to reciprocate along the guides 37a and 37b.

The ions in the dissociated sputtering gas are drawn by the magnetic fields of the magnets 35a and 35b and collide with the targets 31a and 31b. By reciprocating the magnets 35a and 35b by the magnet scanning mechanisms 36a and 36b, the positions at which the ions collide with the targets 31a and 31b, in other words, the positions at which the sputtered particles are ejected, are changed.

A mounting portion 41 of a substrate support 40 for horizontally mounting the wafer W is provided at a position facing the targets 31a and 31b in the processing chamber 10. The mounting portion 41 is connected to a drive mechanism 43 disposed below the processing chamber 10 via a shaft member 42. The drive mechanism 43 has a function of rotating the mounting portion 41.

The shaft member 42 penetrates the bottom of the chamber body 10a and is connected to the drive mechanism 43. A sealing portion 44 for keeping the processing chamber 10 airtight is provided at a position where the shaft member 42 penetrates the bottom of the chamber body 10a.

A heating mechanism (not illustrated) is provided in the mounting portion 41 so as to heat the wafer W during sputtering.

The controller 70 is comprised of a computer and controls the respective components of the substrate processing apparatus 1, such as the power supplies 34a and 34b, the drivers 38a and 38b, the drive mechanism 43, and the exhaust device 60. The controller 70 includes a main controller consisting of a CPU that actually performs these controls, an input device, an output device, a display device, and a storage device. In the storage device, parameters of various processing performed by the substrate processing apparatus 1 are stored, and a storage medium storing a program for controlling the processing performed by the substrate processing apparatus 1, that is, a processing recipe, is set. The main controller of the controller 70 retrieves a predetermined processing recipe stored in the storage medium, and causes the substrate processing apparatus 1 to perform predetermined processing based on the processing recipe.

Next, an example of the film forming process in the substrate processing apparatus 1 will be described. In the present example, a WSiN film is formed as the hard mask 103. When boron (B) is to be contained in a film to be formed, a target containing boron (B) is used as one or both of the target 31a and the target 31b.

First, a wafer W is loaded into the processing chamber 10. Specifically, the controller 70 opens the gate valve 14. The transfer device (not illustrated) provided in the transfer chamber (not illustrated) loads the wafer W into the processing chamber 10 and places the wafer W on the mounting portion 41. When the transfer device retreats from the loading and unloading port 13, the controller 70 closes the gate valve 14.

Next, the film forming process is performed on the wafer W. The controller 70 controls the substrate processing apparatus 1 to form the hard mask 103 (WSiN film) on the wafer W. In the present example, while the mounting portion 41 is rotated, argon (Ar) gas is supplied as a sputtering gas from the gas introduction port 12a, nitrogen (N₂) gas is supplied as a nitrogen-containing gas from the gas introduction port 12b, sputtered particles are ejected from the targets 31a and 31b, and a hard mask 103 (WSiN film) is thereby formed over the wafer W.

Finally, the wafer W is unloaded from the processing chamber 10. Specifically, the controller 70 opens the gate valve 14. The transfer device (not illustrated) provided in the transfer chamber (not illustrated) unloads the wafer W from the mounting portion 41 in the processing chamber 10. When the transfer device retreats from the loading and unloading port 13, the controller 70 closes the gate valve 14.

As described above, according to the substrate processing apparatus 1, an amorphous film (WSIN film) containing tungsten (W), silicon (Si), and nitrogen (N) is formed over the wafer W with the sputtered particles of the first material (W) ejected from the target 31a, the sputtered particles of the second material (WSi) ejected from the target 31b, and the nitrogen (N)-containing gas supplied to the processing chamber 10.

The controller 70 controls the concentration of the first material ejected from the target 31a by controlling the voltage applied from the power supply 34a to the target holder 32a. The controller 70 controls the concentration of the second material ejected from the target 31b by controlling the voltage applied from the power supply 34b to the target holder 32b. The controller 70 controls the flow rate of the nitrogen-containing gas supplied from the gas supplier 20b to the processing chamber 10. In other words, the flow rate ratio between the nitrogen-containing gas and the sputtering gas supplied to the processing chamber 10 is controlled. Thus, the concentrations of tungsten (W), silicon (Si), and nitrogen (N) in the hard mask 103 formed over the wafer W can be adjusted by controlling at least one of the voltage applied to the target 31a (first target), the voltage applied to the target 31b (second target), or the flow rate of the nitrogen-containing gas supplied to the processing chamber 10 (or the flow rate ratio between the nitrogen-containing gas and the sputtering gas supplied to the processing chamber 10).

The combination of the first material and the second material is not limited to the above example. The target 31a may be a target containing tungsten (W), and the target 31b may be a target containing silicon (Si). The target 31a may be a target containing tungsten and silicon (WSi), and the target 31b may be a target containing silicon (Si). Both the target 31a and the target 31b may be targets containing tungsten and silicon (WSi) but having different tungsten-to-silicon ratios. Even with these combinations, the concentrations of tungsten (W), silicon (Si), and nitrogen (N) in the hard mask 103 formed over the wafer W can be adjusted as desired.

Both the target 31a and the target 31b may be targets containing tungsten and silicon (WSi) with the same tungsten-to-silicon ratio. In this case, at least one of the target 31a or the target 31b may be used in the film forming process. Even in this case, the controller 70 can adjust the concentrations of tungsten (W), silicon (Si), and nitrogen (N) in the hard mask 103 formed over the wafer W by controlling at least one of the voltage applied to the target holder 32a and/or the target holder 32b or the flow rate of the nitrogen-containing gas (or the flow rate ratio between the nitrogen-containing gas and the sputtering gas). In the present example, a WSiN film is formed as the hard mask 103; however, when boron (B) is contained in the hard mask 103, a target containing boron (B) is used as one or both of the targets 31a and 31b. If boron (B) is contained, oxidation can be further suppressed.

Tungsten silicide (WSi) films formed by a chemical vapor deposition method have crystal grain boundaries of metal crystals. For this reason, tungsten silicide films formed by a chemical vapor deposition method have low resistance to plasma etching at crystal grain boundaries, and the portion where crystal grain boundaries are present is etched too early.

On the other hand, the substrate processing apparatus 1 illustrated in FIG. 3 forms an amorphous film having substantially no crystal grain boundaries as the hard mask 103. Thus, the hard mask 103 has high resistance to plasma etching. In etching of the wafer W (step S105), the selection ratio between the hard mask 103 and the base film 102 can be increased. In other words, the film thickness of the hard mask 103 can be reduced. By reducing the film thickness of the hard mask 103, the occurrence of twisting due to hindrance of normal incidence of ions can be reduced.

### Etching of Hard Mask

Next, the shape of the openings 112 formed by etching the hard mask 103 in step S104 will be described in comparison with a comparative example.

An element in an electronic device often has an electrode formed of tungsten and a film containing silicon. Accordingly, tungsten silicide is a desirable material for constituting a hard mask for plasma etching. However, a hard mask formed of tungsten silicide is partially etched too early.

If the thickness of a hard mask is increased so that the hard mask will remain until the end of plasma etching, there is a risk of warping a workpiece due to a film stress of the hard mask.

Under such circumstances, a hard mask having high resistance to plasma etching is demanded, Because a hard mask having high resistance is difficult to etch, a method of alternately performing sidewall oxidation and etching is often used. However, when the sidewall oxidation is excessive, there arises a problem in that the pattern shape deteriorates.

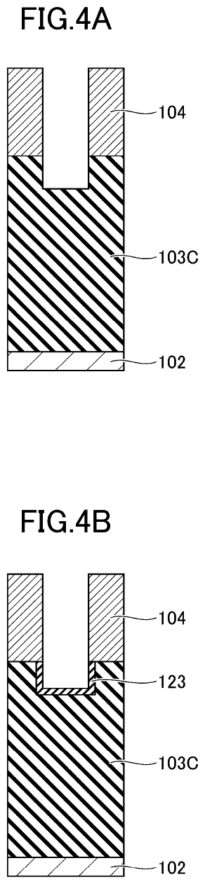

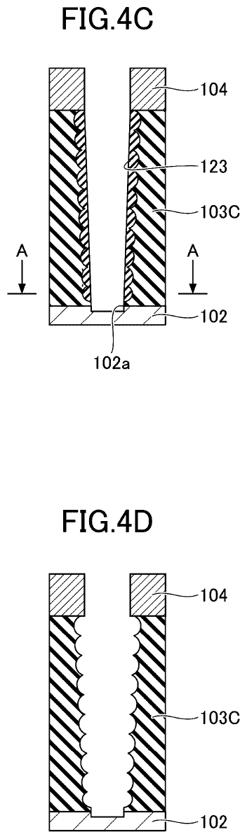

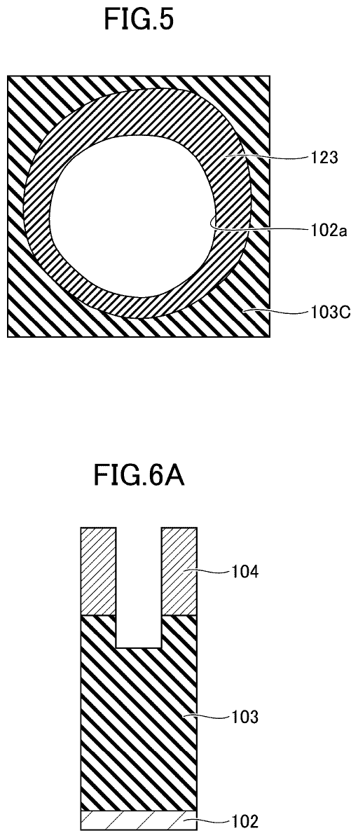

The shape of the openings 112 formed by etching a hard mask 103C according to the comparative example will be first described with reference to FIGS. 4A through 4D and 5. FIGS. 4A through 4D are examples of schematic cross-sectional views illustrating an example of processing of the hard mask 103C according to the comparative example.

The hard mask 103C according to the comparative example is an amorphous film (WSi film) containing tungsten (W) and silicon (Si). The hard mask 103C having a composition of 60 at.% tungsten (W) and 40 at.% silicon (Si) is formed without a supply of a nitrogen-containing gas, using the substrate processing apparatus 1 illustrated in FIG. 3.

When the hard mask 103C is etched using the silicon oxide film 104, in which openings are formed, as a mask, a step of etching the hard mask 103C and a step of oxidizing the sidewalls of the recesses of the hard mask 103C are alternately repeated.

In the step of etching the hard mask 103C, the hard mask 103C is etched as illustrated in FIG. 4A, using the amorphous carbon film 105 and the silicon oxide film 104 having openings as masks.

As illustrated in FIG. 4b, in the step of oxidizing the sidewalls of the recesses of the hard mask 103C, the sidewalls and bottom walls of the recesses of the hard mask 103C formed by etching are oxidized by an oxygen (O)-containing plasma to form an oxide layer 123.

As described above, in the plasma etching of the hard mask 103C, the etching illustrated in FIG. 4A and the formation of the oxide layer 123 illustrated in FIG. 4B are alternately repeated, thereby allowing the etching of the hard mask 103C to proceed further.

FIG. 4C illustrates a state in which etching has been carried out until penetrating through the hard mask 103C. As illustrated in FIG. 4C, the thickness of the oxide layer 123 formed on the sidewalls of the opening is uneven.

FIG. 4D illustrates a state after DHF (diluted hydrofluoric acid) cleaning of the hard mask 103C. The oxide layer 123 is removed by DHF cleaning. As a result, as illustrated in FIG. 4D, the shape of the opening of the hard mask 103C is deteriorated. For example, local critical dimension uniformity (LCDU) is deteriorated.

FIG. 5 is an example of a cross-sectional view of the hard mask 1030 according to the comparative example taken along line A-A of FIG. 4C. FIG. 5 is a top view of the cross-section taken along line A-A. Hatching is applied to the cross-sectional portion of the hard mask 103C and the cross-sectional portion of the oxide layer 123. Reference numeral 102a denotes an edge of an opening of the hard mask 103C at a boundary surface with the base film 102.

As illustrated in FIG. 5, in the plasma etching of the hard mask 103C, the roundness of the edge 102a of the opening is also deteriorated. Furthermore, the thickness of the oxide layer 123 is uneven.

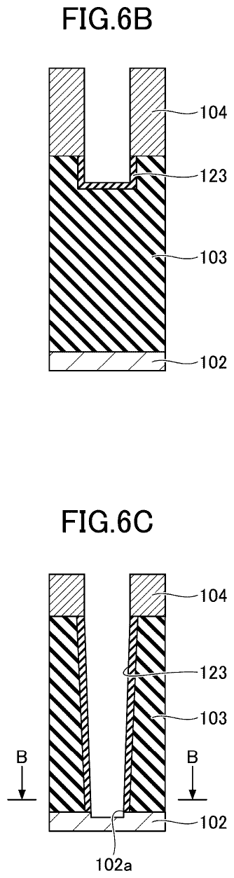

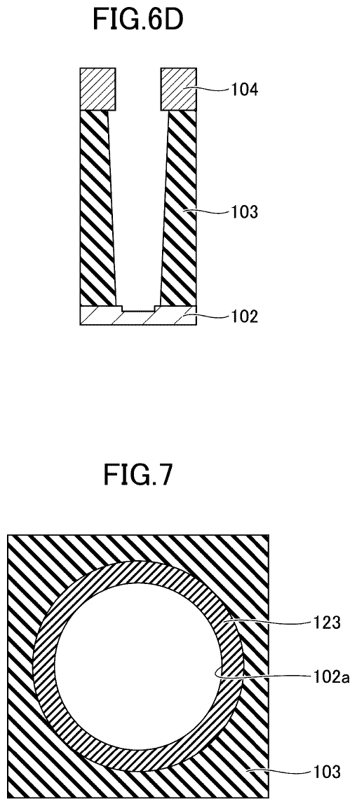

The shape of the openings 112 formed by etching the hard mask 103 according to the present embodiment will be described with reference to FIGS. 6A through 6D and 7. FIGS. 6A through 6D are schematic cross-sectional views illustrating an example of processing of the hard mask 103 according to the present embodiment.

In the present example, the hard mask 103 according to the present embodiment is an amorphous film (WSIN film) containing tungsten (W), silicon (Si), and nitrogen (N). The hard mask 103 having a composition of 60 at.% tungsten (W), 25 at.% silicon (Si), and 15 at.% nitrogen (N) is formed using the substrate processing apparatus 1 illustrated in FIG. 3.

When the hard mask 103 is etched using the silicon oxide film 104, in which openings are formed, as a mask, a step of etching the hard mask 103 and a step of oxidizing the sidewalls of the recesses of the hard mask 103 are alternately repeated.

In the step of etching the hard mask 103, the hard mask 103 is etched, as illustrated in FIG. 6A, using the amorphous carbon film 105 having openings and the silicon oxide film 104 as masks.

As illustrated in FIG. 6B, in the step of oxidizing the sidewalls of the recesses of the hard mask 103, the sidewalls and bottom walls of the recesses of the hard mask 103 formed by etching are oxidized by an oxygen (O)-containing plasma to form an oxide layer 123.

As described above, in the plasma etching of the hard mask 103, the etching illustrated in FIG. 6A and the formation of the oxide layer 123 illustrated in FIG. 6B are alternately repeated, thereby allowing the etching of the hard mask 103 to proceed further.

FIG. 6C illustrates a state in which etching has been carried out until penetrating through the hard mask 103. As illustrated in FIG. 6C, non-uniformity of the film thickness of the oxide layer 123 formed on the sidewalls of the openings is suppressed.

FIG. 6D illustrates a state after DHF cleaning of the hard mask 103. The oxide layer 123 is removed by DHF cleaning. As a result, as illustrated in FIG. 6D, the shape of the opening of the hard mask 103C is improved as compared with the comparative example. For example, local critical dimension uniformity (LCDU) is improved.

FIG. 7 is an example of a cross-sectional view of the hard mask 103 according to the present embodiment taken along line B-B of FIG. 6C. FIG. 7 is a top view of the cross-section taken along line B-B. Hatching is applied to the cross-sectional portion of the hard mask 103 and the cross-sectional portion of the oxide layer 123. Reference numeral 102a denotes an edge of an opening of the hard mask 103 at a boundary surface with the base film 102.

As illustrated in FIG. 7, in the plasma etching of the hard mask 103, the roundness of the edge 102a of the opening is improved. In addition, the thickness of the oxide layer 123 is prevented from becoming uneven.

Although the hard mask 103 made of an amorphous film (WSIN film) containing tungsten (W), silicon (Si), and nitrogen (N) has been described as having a uniform atomic concentration as a whole, the present embodiment is not limited to this example. The hard mask 103 may be a film in which the atomic concentration of silicon (Si) is modulated in the depth direction.

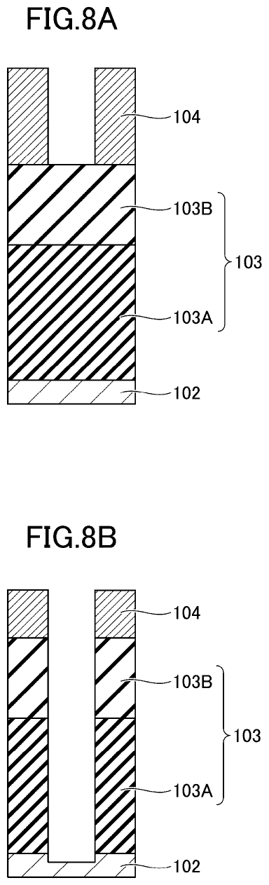

FIGS. 8A and 8B illustrate another example of the hard mask 103 according to the present embodiment.

As illustrated in FIG. 8A, the hard mask 103 has a first WSiN film 103A and a second WSiN film 103B. The atomic concentration of silicon (Si) in the second WSIN film 103B is higher than that in the first WSiN film 103A.

In the present example, when the hard mask 103 is etched using the silicon oxide film 104, in which openings are formed, as a mask, a step of etching the hard mask 103 and a step of oxidizing the sidewalls of the recesses of the hard mask 103 are alternately repeated. For this reason, since the upper portion of the hard mask 103 is repeatedly exposed to the etching gas in comparison with the lower portion of the hard mask 103, there is a risk of bowing occurring on the upper side of the openings formed in the hard mask 103. In particular, the higher the aspect ratio, the greater the risk of bowing occurring.

To address this situation, as illustrated in FIG. 8B, the atomic concentration of silicon (Si) in the second WSiN film 103B, which is located in the upper portion, is made higher than that in the first WSiN film 103A. In the etching process, a large amount of silicon oxide, which is relatively less volatile than tungsten oxide, is present in the sidewalls, so that occurrence of bowing on the upper side of the openings formed in the hard mask 103 can be suppressed.

The first WSiN film 103A and the second WSiN film 103B can be continuously formed in the processing chamber 10 of the substrate processing apparatus 1. After the first WSiN film 103A is formed, the second WSiN film 103B having a higher atomic concentration of silicon than that in the first WSiN film 103A can be formed by changing the voltage applied to the target and the flow rate of the nitrogen-containing gas supplied to the processing chamber 10. By continuously forming the first WSiN film 103A and the second WSIN film 103B in the same chamber, a high throughput can be obtained.

Although the hard mask 103 is formed by two layers of the first WSIN film 103A and the second WSIN film 103B as an example, the present embodiment is not limited to this example. For example, the atomic concentration of silicon in the hard mask 103 may increase from the lower portion to the upper portion, either across three or more discrete layers or in a continuous (stepless) manner. Even in this case, it is possible to continuously form films by changing the voltage applied to the target and the flow rate of the nitrogen-containing gas supplied to the processing chamber 10 in the processing chamber 10 of the substrate processing apparatus 1.

Although the substrate processing method has been described above, the present disclosure is not limited to the above embodiments, and various modifications and improvements are possible within the scope of the present disclosure described in the appended claims.

What is claimed is:

1. A substrate processing method, comprising:
preparing a substrate having a silicon-containing film; and
forming a hard mask on the silicon-containing film by sputtering, the hard mask being an amorphous film containing tungsten, silicon, and nitrogen.

2. The substrate processing method according to claim 1, wherein
the hard mask is formed by causing a target containing tungsten and silicon to be sputtered.

3. The substrate processing method according to claim 2, wherein
a composition of tungsten, silicon, and nitrogen in the hard mask is adjusted by controlling at least one of a voltage applied to the target or a flow rate of a nitrogen-containing gas supplied to a processing chamber.

4. The substrate processing method according to claim 3, wherein
the target includes a first target containing tungsten and a second target containing tungsten and silicon.

5. The substrate processing method according to claim 4, wherein
the composition of tungsten, silicon, and nitrogen in the hard mask is adjusted by controlling at least one of a voltage applied to the first target, a voltage applied to the second target, or the flow rate of the nitrogen-containing gas supplied to the processing chamber.

6. The substrate processing method according to claim 4, wherein
the composition of tungsten, silicon, and nitrogen in the hard mask is adjusted by controlling at least one of a voltage applied to the first target, a voltage applied to the second target, or a flow rate ratio between a sputtering gas supplied to the processing chamber and the nitrogen-containing gas supplied to the processing chamber.

7. The substrate processing method according to claim 1, wherein
the hard mask further contains boron.

8. The substrate processing method according to claim 7, wherein
an atomic concentration of tungsten contained in the hard mask is 50 to 60 at.%,
an atomic concentration of silicon contained in the hard mask is 20 to 30 at.%,
an atomic concentration of nitrogen contained in the hard mask is 15-25 at.%,
an atomic concentration of boron contained in the hard mask is 0-15 at.%, and
a total atomic concentration of tungsten, silicon, nitrogen, and boron contained in the hard mask is 100 at.%.

9. The substrate processing method according to claim 1, wherein
an atomic concentration of silicon in the hard mask is density-modulated in a depth direction.

10. The substrate processing method according to claim 9, wherein
an upper portion of the hard mask has a higher atomic concentration of silicon than a lower portion of the hard mask.

11. A substrate processing apparatus comprising:
a processing chamber ;
a substrate support configured to support a substrate;
a first target containing at least tungsten;
a second target containing at least silicon;
a first power supply configured to apply a voltage to the first target;
a second power supply configured to apply a voltage to the second target;
a first gas supply configured to supply a sputtering gas;
a second gas supply configured to supply a nitrogen-containing gas; and
a controller, wherein
the controller is configured to perform
preparing a substrate having a silicon-containing film by placing the substrate on the substrate support; and
forming a hard mask on the silicon-containing film by sputtering, the hard mask being an amorphous film containing tungsten, silicon, and nitrogen.

12. The substrate processing apparatus according to claim 11, wherein
the controller is configured to adjust a concentration of tungsten, silicon, or nitrogen in the hard mask by controlling at least one of a voltage applied to the first target, a voltage applied to the second target, or a flow rate ratio between a sputtering gas supplied to the processing chamber and a nitrogen-containing gas supplied to the processing chamber.

13. The substrate processing apparatus according to claim 11, wherein
the hard mask further contains boron.

14. A hard mask for plasma etching formed over a silicon-containing film, the hard mask being an amorphous film containing tungsten, silicon, and nitrogen.

15. The hard mask according to claim 14, wherein the hard mask further contains boron.

16. The hard mask according to claim 15, wherein
an atomic concentration of tungsten contained in the hard mask is 50 to 60 at.%,
an atomic concentration of silicon contained in the hard mask is 20 to 30 at.%,
an atomic concentration of nitrogen contained in the hard mask is 15 to 25 at.%,
an atomic concentration of boron contained in the hard mask is 0 to 15 at.%, and
a total atomic concentration of tungsten, silicon, nitrogen, and boron contained in the hard mask is 100 at.%.
